(19) United States
(12) Patent Application Publication
(10) Pub. No.: US 2026/0215173 A1
(43) Pub. Date: Jul. 23, 2026

(54) METHOD FOR MANUFACTURING SEMICONDUCTOR COMPONENTS, THIN FILM ACTUATOR AND THIN FILM GRIPPER

(71) Applicant: POSTECH RESEARCH AND BUSINESS DEVELOPMENT FOUNDATION, Pohang-si (KR)

(72) Inventors: Seok KIM, Pohang-si (KR); Sang Yeop LEE, Pohang-si (KR); Changhee SON, Pohang-si (KR)

(73) Assignee: POSTECH RESEARCH AND BUSINESS DEVELOPMENT FOUNDATION, Pohang-si (KR)

(21) Appl. No.: 19/445,389

(22) Filed: Jan. 9, 2026

(30) Foreign Application Priority Data
Jan. 23, 2025 (KR) 10-2025-0009940

(51) Int. Cl. H10P 10/00; H10P 56/00

(52) U.S. Cl. CPC H10P 10/128; H10P 56/00

(57) ABSTRACT

A semiconductor component manufacturing method includes preparing a thin device layer having a first semiconductor component element formed on one surface thereof, placing the device layer on a front-side support substrate such that the one surface of the device layer is in direct contact with the front-side support substrate, forming a second semiconductor component element on an opposite surface of the device layer facing away from the one surface, and separating the device layer from the front-side support substrate, wherein, in placing the device layer on the front-side support substrate, the device layer is fixed to the front-side support substrate by a van der Waals force acting between the device layer and the front-side support substrate.

### CROSS REFERENCE TO RELATED APPLICATION

This application claims priority from Republic of Korea Patent Application No. 10-2025-0009940, filed on Jan. 23, 2025, the content of which is all hereby incorporated by reference herein in their entirety.

### BACKGROUND OF THE INVENTION

### Field of the Invention

The present disclosure relates to a method for manufacturing a semiconductor component, a thin-film actuator, and a thin-film gripper, and more particularly to a method for manufacturing a semiconductor component, and a thin-film actuator and a thin-film gripper manufactured using the same.

### Related Art

In the fabrication of semiconductor components using a wafer, a wafer thinning process is performed in order to reduce the thickness of the semiconductor components.

Because a semiconductor substrate having a reduced thickness exhibits high brittleness and is therefore susceptible to fracture or damage during a transfer process or during semiconductor processing, a process is generally performed in which semiconductor devices are first formed on a front surface of a wafer having a thickness sufficient to ensure rigidity, and thereafter a thinning process is carried out by physically or chemically etching a rear surface of the wafer.

Accordingly, semiconductor devices have been formed only on the front surface of the wafer and could not be formed on the rear surface thereof. In addition, since the thinning process is performed after the semiconductor devices are formed, the thinning process may cause physical and/or chemical damage to the semiconductor devices.

### SUMMARY OF THE INVENTION

An object of the present disclosure is to provide a method for manufacturing a semiconductor component that allows a thinning process to be performed prior to a process of forming semiconductor devices.

Another object of the present disclosure is to provide a method for manufacturing a semiconductor component that enables semiconductor devices and the like to be formed on both surfaces of a semiconductor material.

Another object of the present disclosure is to provide a thin-film actuator.

Another object of the present disclosure is to provide a thin-film gripper.

The objects of the present disclosure are not limited to those described above, and other objects not explicitly mentioned herein will be clearly understood by those skilled in the art from the following description.

A method for manufacturing a semiconductor component includes preparing a thin device layer having a first semiconductor component element formed on one surface thereof, placing the device layer on a front-side support substrate such that the one surface of the device layer is in direct contact with the front-side support substrate, forming a second semiconductor component element on an opposite surface of the device layer facing away from the one surface and separating the device layer from the front-side support substrate, wherein, in placing the device layer on the front-side support substrate, the device layer is fixed to the front-side support substrate by a van der Waals force acting between the device layer and the front-side support substrate.

A thin-film actuator according to an embodiment of the present disclosure includes a thin device layer, a first heating layer formed on a front surface of the device layer and having a coefficient of thermal expansion different from that of the device layer, and a second heating layer formed on a rear surface of the device layer and having a coefficient of thermal expansion different from that of the device layer.

A thin-film actuator according to an embodiment of the present disclosure includes a thin device layer, a heating layer formed on a front surface of the device layer and having a coefficient of thermal expansion different from that of the device layer, and a shape control layer formed on a rear surface of the device layer and configured to control deformation of the device layer in response to deformation of the heating layer.

A thin-film gripper according to an embodiment of the present disclosure includes a thin device layer including a first finger thin film and a second finger thin film formed adjacent to each other, a first heating layer formed on a front surface of the first finger thin film and having a coefficient of thermal expansion different from that of the first finger thin film, and a second heating layer formed on a rear surface of the second finger thin film and having a coefficient of thermal expansion different from that of the second finger thin film.

Other details of the disclosure are included in the detailed description and the accompanying drawings.

According to the embodiments of the disclosure, the effects are at least as follows.

Since a thinning process is not performed after semiconductor devices are formed, the possibility of damage to the semiconductor devices can be reduced.

Semiconductor devices and the like can be formed on both surfaces of a semiconductor material.

A thin-film actuator can be manufactured.

A thin-film gripper can be manufactured.

The effects of the disclosure are not limited to those described above, and various other effects are included in the foregoing description.

### BRIEF DESCRIPTION OF THE DRAWINGS

FIG. 1 is a diagram for explaining a semiconductor component manufacturing method according to a first embodiment of the present invention.

FIG. 2 is a diagram for explaining a semiconductor component manufacturing method according to a second embodiment of the present invention.

FIG. 3 is a diagram for explaining a semiconductor component manufacturing method according to a third embodiment of the present invention.

FIG. 4 is a diagram for explaining a semiconductor component manufacturing method according to a fourth embodiment of the present invention.

FIG. 5 is an exploded perspective view illustrating a thin-film actuator according to the first embodiment of the present invention.

FIG. 6 is a schematic side view illustrating an operating state of the thin-film actuator according to the first embodiment of the present invention.

FIG. 7 is a schematic side view illustrating another embodiment of the thin-film actuator according to the first embodiment of the present invention.

FIG. 8 is an exploded perspective view illustrating a thin-film actuator according to a second embodiment of the present invention.

FIG. 9 is an image illustrating an operating state of the thin-film actuator according to the second embodiment of the present invention.

FIG. 10 is an exploded perspective view illustrating a thin-film gripper according to an embodiment of the present invention.

FIG. 11 is an image illustrating operation simulation results of the thin-film gripper according to an embodiment of the present invention.

FIG. 12 is an image illustrating a pick-and-place operation using the thin-film gripper according to an embodiment of the present invention.

### DETAILED DESCRIPTION

The advantages and features of the present invention, and methods for achieving the same, will become apparent from the embodiments described in detail below with reference to the accompanying drawings. However, the present invention is not limited to the embodiments disclosed herein and may be implemented in various different forms. The embodiments are provided merely to complete the disclosure of the present invention and to fully convey the scope of the invention to those skilled in the art, and the present invention is defined only by the scope of the claims.

In addition, the embodiments described herein will be explained with reference to idealized cross-sectional views and/or schematic views of the present invention. Accordingly, the shapes shown in the drawings may be modified depending on manufacturing techniques and/or tolerances. Further, in the drawings, components may be illustrated with exaggerated or reduced dimensions for clarity of description. Throughout the specification, like reference numerals refer to like elements.

Hereinafter, the present invention will be described with reference to the drawings for explaining a semiconductor component manufacturing method, and a thin-film actuator and a thin-film gripper manufactured using the same, according to embodiments of the present invention.

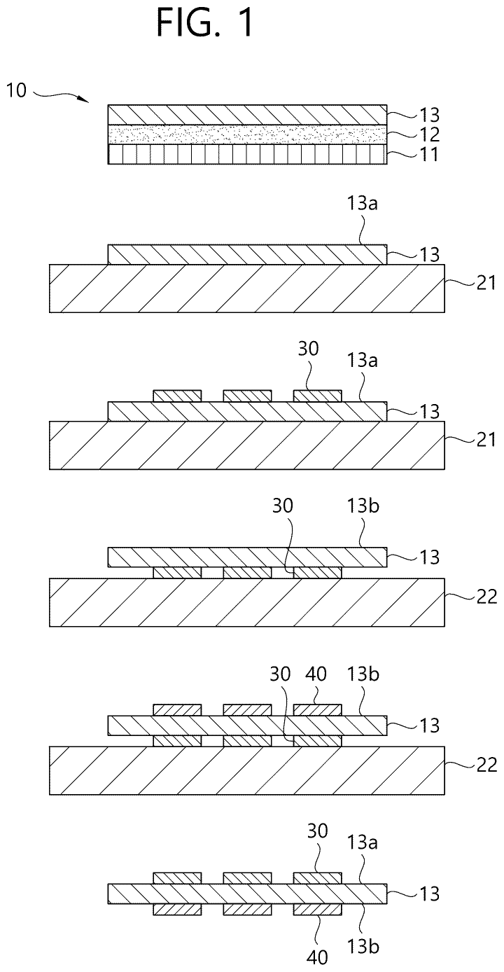

FIG. 1 is a diagram for explaining a semiconductor component manufacturing method according to a first embodiment of the present invention.

Referring to FIG. 1, the semiconductor component manufacturing method according to the first embodiment of the present invention includes: preparing a silicon-on-insulator (SOI) wafer 10; separating a device layer 13 from the SOI wafer 10; placing the separated device layer 13 on a rear-side support substrate 21; forming a first semiconductor component element 30 on one surface of the device layer 13; separating the device layer 13 from the rear-side support substrate 21; placing the device layer 13 on a front-side support substrate 22; forming a second semiconductor component element 40 on the other surface of the device layer 13; and separating the device layer 13 from the front-side support substrate 22.

The SOI wafer 10 may include a handling layer 11, a silicon oxide (SiO₂) layer 12 stacked on the handling layer 11, and a device layer 13 stacked on the silicon oxide layer 12. The SOI wafer 10 may have a thickness ranging from several micrometers to several hundreds of micrometers. The device layer 13 may be formed of a silicon (Si) layer and may be a thin film having a thickness ranging from several tens of nanometers to several tens of micrometers.

The step of separating the device layer 13 from the SOI wafer 10 may include removing the silicon oxide layer 12 and separating the device layer 13 from the handling layer 11.

In the step of removing the silicon oxide layer 12, the SOI wafer 10 may be immersed in an etching solution that selectively etches silicon oxide. The etching solution may include, for example, a hydrofluoric acid solution or an acetic acid solution. Since the etching solution selectively etches the silicon oxide layer 12 of the SOI wafer 10, the SOI wafer 10 immersed in the etching solution remains as the handling layer 11 and the device layer 13.

After the silicon oxide layer 12 is removed, the SOI wafer 10 may be rinsed with a cleaning liquid such as deionized (DI) water so as to remove any etching solution remaining on the SOI wafer 10.

In the step of separating the device layer 13 from the handling layer 11, the SOI wafer 10 from which the silicon oxide layer 12 has been removed may be immersed in a separation solution. The separation solution may include, for example, deionized (DI) water or an acetic acid solution. In the separation solution, the handling layer 11 and the device layer 13 are separated from each other.

In some embodiments, during the step of removing the silicon oxide layer 12, the silicon oxide layer 12 may be etched such that the handling layer 11 and the device layer 13 are already in a separated state. In this case, a separate step of separating the device layer 13 from the handling layer 11 may be omitted.

The step of placing the separated device layer 13 on the rear-side support substrate 21 may include inserting the rear-side support substrate 21 between the device layer 13 and the handling layer 11, placing the device layer 13 on the rear-side support substrate 21, and bringing the device layer 13 into close contact with the rear-side support substrate 21.

In the step of inserting the rear-side support substrate 21 between the device layer 13 and the handling layer 11, the rear-side support substrate 21 may be introduced into a predetermined solution in which the device layer 13 and the handling layer 11 remain in a separated state, and may be inserted between the device layer 13 and the handling layer 11.

When the device layer 13 and the handling layer 11 are separated in the separation solution, the predetermined solution may be the separation solution. Alternatively, when the device layer 13 and the handling layer 11 are separated in the etching solution, the predetermined solution may be the etching solution. Alternatively, when the device layer 13 and the handling layer 11 are separated in a cleaning solution, the predetermined solution may be the cleaning solution.

The rear-side support substrate 21 should stably support the thin device layer 13 so that a first semiconductor component element 30, which will be described later, can be formed on the device layer 13, and should have resistance to chemicals used during the formation of the first semiconductor component element 30 as well as sufficient rigidity to withstand applied physical forces. The rear-side support substrate 21 may include, for example, a glass substrate, a quartz substrate, or a silicon substrate, and may be a substrate to which a hydrophobic coating (for example, a silane coating) is applied.

In the step of placing the device layer 13 on the rear-side support substrate 21, the rear-side support substrate 21, which has been inserted below the device layer 13 in the predetermined solution, may be raised so that the device layer 13 is placed on the rear-side support substrate 21. The device layer 13 may be placed on the rear-side support substrate 21 such that an opposite surface (lower surface) 13b of the device layer 13 faces the rear-side support substrate 21.

In the step of bringing the device layer 13 into close contact with the rear-side support substrate 21, after the device layer 13 is placed on the rear-side support substrate 21, the rear-side support substrate 21 may be taken out of the predetermined solution, and the predetermined solution may be dried so that the device layer 13 and the rear-side support substrate 21 are brought into close contact with each other. As the predetermined solution between the device layer 13 and the rear-side support substrate 21 is dried, the device layer 13 may be fixed on the rear-side support substrate 21 by van der Waals forces acting between the device layer 13 and the rear-side support substrate 21, without using a separate adhesive or bonding material.

In the step of forming the first semiconductor component element 30 on one surface of the device layer 13, a process for forming the first semiconductor component element 30 is performed on one surface 13a of the device layer 13. The one surface 13a of the device layer 13 may be a surface opposite to the opposite surface 13b that is in contact with the rear-side support substrate 21. The process for forming the first semiconductor component element 30 may include lithography processes, etching processes, deposition processes, and the like.

Since the device layer 13 is fixed to the rear support substrate 21 by a van der Waals force, and the rear support substrate 21 supports forces applied during a process of forming a first semiconductor component element 30, the first semiconductor component element 30 can be formed on one surface 13a of the thin device layer 13.

The first semiconductor component element 30 is a concept that encompasses semiconductor devices such as diodes, transistors, resistors, and integrated circuits, as well as parts of semiconductor devices or structures for forming semiconductor devices.

In the step of separating the device layer 13 from the rear support substrate 21, the device layer 13 on which the first semiconductor component element 30 is formed and the rear support substrate 21 may be immersed in a separation solution. In the separation solution, the device layer 13 and the rear support substrate 21 are separated from each other. Alternatively, the separation solution may be sprayed onto the device layer 13 and the rear support substrate 21 to separate the device layer 13 from the rear support substrate 21.

As the device layer 13 and the rear support substrate 21 are separated from each other, a thin device layer 13 having the first semiconductor component element 30 formed on one surface 13a is prepared.

In a step of placing the device layer 13 on a front support substrate 22, the device layer 13 is placed on the front support substrate 22 such that the one surface 13a of the device layer 13 faces the front support substrate 22.

For example, the front support substrate 22 may be introduced into the separation solution in which the device layer 13 is immersed, and then lifted together with the device layer 13 from the separation solution while the one surface 13a of the device layer 13 is in contact with the front support substrate 22. For this purpose, in the step of separating the device layer 13 from the rear support substrate 21, the device layer 13 may be immersed in the separation solution with the one surface 13a facing downward. After the rear support substrate 21 separated from the device layer 13 is removed from the separation solution, the front support substrate 22 may be introduced into the separation solution such that the one surface 13a of the device layer 13 comes into contact with the front support substrate 22, thereby allowing the device layer 13 to be placed on the front support substrate 22.

The front support substrate 22 may be identical to the rear support substrate 21. Alternatively, a front support substrate 22 having rigidity and chemical resistance required for a process of forming a second semiconductor component element 40, which will be described later, may be used. The front support substrate 22 may include a glass substrate, a quartz substrate, or a silicon substrate, and a substrate to which a hydrophobic coating, such as a silane coating, is applied may be used.

The step of placing the device layer 13 on the front support substrate 22 may further include a step of bringing the device layer 13 into close contact with the front support substrate 22.

In the step of bringing the device layer 13 into close contact with the front support substrate 22, after the front support substrate 22 with the device layer 13 placed thereon is lifted from the separation solution, the separation solution may be dried so that the device layer 13 and the front support substrate 22 come into close contact with each other. As the separation solution between the device layer 13 and the front support substrate 22 is dried, the device layer 13 may be fixed to the front support substrate 22 by a van der Waals force acting therebetween, without using a separate adhesive or tacky material.

Although the first semiconductor component element 30 is formed on the one surface of the device layer 13, since the device layer 13 is a thin-film layer, the device layer 13 can come into close contact with the front support substrate 22 even when the first semiconductor component element 30 is present between the device layer 13 and the front support substrate 22.

In a step of forming a second semiconductor component element 40 on the opposite surface of the device layer 13, a process of forming the second semiconductor component element 40 is performed on the opposite surface 13b of the device layer 13. The opposite surface 13b of the device layer 13 may be a surface located opposite to the one surface 13a that is in contact with the front support substrate 22. The process of forming the second semiconductor component element 40 may include a lithography process, an etching process, a deposition process, or the like.

Since the device layer 13 is fixed to the front support substrate 22 by a van der Waals force, and the front support substrate 22 supports forces applied during a process of forming the second semiconductor component element 40, the second semiconductor component element 40 can be formed on the opposite surface 13b of the thin device layer 13.

The second semiconductor component element 40 is a concept that encompasses semiconductor devices such as diodes, transistors, resistors, and integrated circuits, as well as parts of semiconductor devices or structures for forming semiconductor devices. The second semiconductor component element 40 may be identical to or different from the first semiconductor component element 30.

In a step of separating the device layer 13 from the front support substrate 22, the device layer 13 on which the first semiconductor component element 30 and the second semiconductor component element 40 are formed, and the front support substrate 22, may be immersed in a separation solution. In the separation solution, the device layer 13 and the front support substrate 22 are separated from each other. Alternatively, the separation solution may be sprayed onto the device layer 13 and the front support substrate 22 to separate the device layer 13 from the front support substrate 22.

As the device layer 13 and the front support substrate 22 are separated from each other, a thin semiconductor component is fabricated in which the first semiconductor component element 30 and the second semiconductor component element 40 are respectively formed on both surfaces 13a and 13b of the thin device layer 13.

Hereinafter, a semiconductor component manufacturing method according to another embodiment of the present invention will be described. For convenience of description, components similar to those of the semiconductor component manufacturing method according to the above-described first embodiment are denoted by the same reference numerals, and descriptions of parts common to the semiconductor component manufacturing method according to the above-described first embodiment will be omitted.

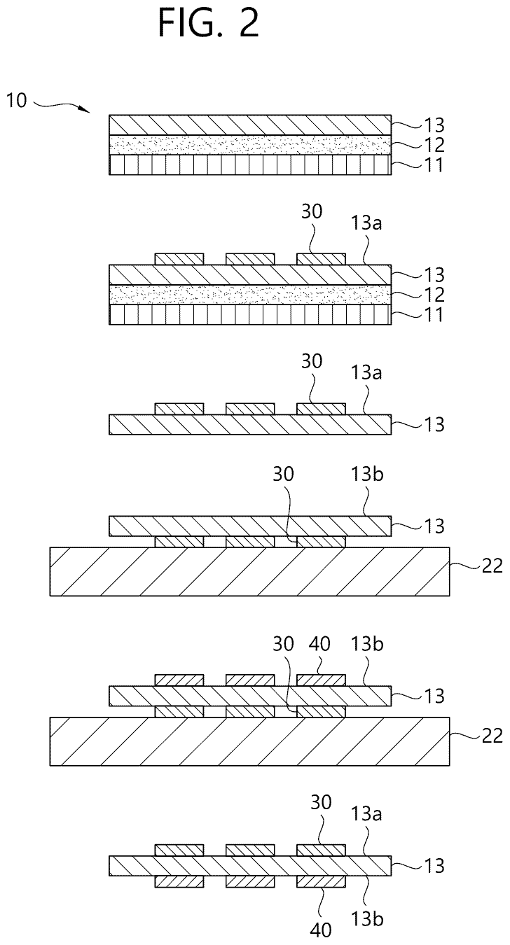

FIG. 2 is a diagram for explaining a semiconductor component manufacturing method according to a second embodiment of the present invention.

Referring to FIG. 2, the semiconductor component manufacturing method according to the second embodiment of the present invention differs from the semiconductor component manufacturing method according to the above-described first embodiment in that the device layer 13 is peeled from the SOI wafer 10 after the first semiconductor component element 30 is formed on the SOI wafer 10.

The semiconductor component manufacturing method according to the second embodiment of the present invention includes preparing an SOI wafer 10, forming a first semiconductor component element 30 on one surface of a device layer 13 of the SOI wafer 10, peeling the device layer 13 from the SOI wafer 10, placing the device layer 13 on a front support substrate 22, forming a second semiconductor component element 40 on the opposite surface of the device layer 13, and separating the device layer 13 from the front support substrate 22.

Since the SOI wafer 10 has been described above, a further description thereof will be omitted.

In a step of forming a first semiconductor component element 30 on one surface of the device layer 13 of the SOI wafer 10, a process of forming the first semiconductor component element 30 is performed on the one surface 13a of the device layer 13. The process of forming the first semiconductor component element 30 may include a lithography process, an etching process, a deposition process, or the like.

The step of peeling the device layer 13 from the SOI wafer 10 may include a step of removing the silicon oxide layer 12 and a step of separating the device layer 13 from the handling layer 11.

In the step of removing the silicon oxide layer 12, the SOI wafer 10 on which the first semiconductor component element 30 is formed may be immersed in an etching solution that selectively etches silicon oxide. The silicon oxide layer 12 of the SOI wafer 10 is etched by the etching solution, and the SOI wafer 10 immersed in the etching solution remains as the handling layer 11 and the device layer 13 on which the first semiconductor component element 30 is formed.

The SOI wafer 10 from which the silicon oxide layer 12 has been removed may be cleaned using a cleaning liquid such as DI water (Deionized Water) so as to remove the etching solution remaining on the SOI wafer 10.

In the step of separating the device layer 13 from the handling layer 11, the SOI wafer 10 from which the silicon oxide layer 12 has been removed may be immersed in a separation solution. In the separation solution, the handling layer 11 and the device layer 13 are separated from each other.

During the step of removing the silicon oxide layer 12, the silicon oxide layer 12 may be etched such that the handling layer 11 and the device layer 13 are brought into a separated state. In this case, a separate step of separating the device layer 13 from the handling layer 11 may be omitted.

The steps of placing the device layer 13 on the front support substrate 22, forming the second semiconductor component element 40 on the opposite surface of the device layer 13, and separating the device layer 13 from the front support substrate 22 have been described above with reference to the semiconductor component manufacturing method according to the first embodiment, and thus further descriptions thereof will be omitted.

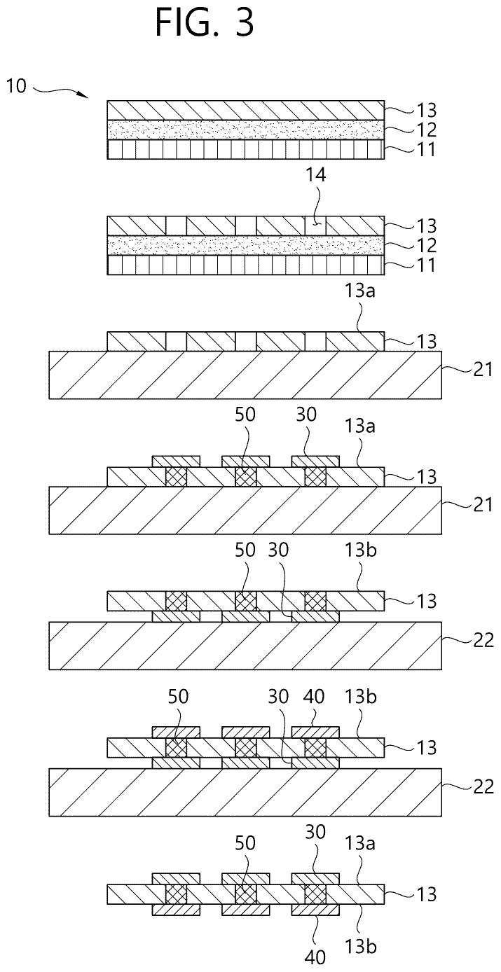

FIG. 3 is a diagram for explaining a semiconductor component manufacturing method according to a third embodiment of the present invention.

Referring to FIG. 3, the semiconductor component manufacturing method according to the third embodiment of the present invention differs from the semiconductor component manufacturing method according to the above-described first embodiment in that a via hole 14 is formed in the device layer 13 before the device layer 13 is peeled from the SOI wafer 10.

The semiconductor component manufacturing method according to the third embodiment of the present invention includes preparing an SOI wafer 10, forming a via hole 14 in a device layer 13, peeling the device layer 13 from the SOI wafer 10, placing the peeled device layer 13 on a rear support substrate 21, forming a third semiconductor component element 50 in the via hole 14, forming a first semiconductor component element 30 on one surface of the device layer 13, separating the device layer 13 from the rear support substrate 21, placing the device layer 13 on a front support substrate 22, forming a second semiconductor component element 40 on a opposite surface of the device layer 13, and separating the device layer 13 from the front support substrate 22.

Descriptions of the SOI wafer 10 have been provided above, and thus additional descriptions thereof will be omitted.

In a step of forming a via hole 14 in the device layer 13, at least one via hole 14 connecting one surface 13a and a opposite surface 13b of the device layer 13 is formed. For example, the via hole 14 may be formed using DRIE (Deep Reactive Ion Etching) or a laser. However, the process for forming the via hole 14 is not limited thereto, and the via hole 14 may be formed by other processes.

The step of peeling the device layer 13 from the SOI wafer 10 and the step of placing the peeled device layer 13 on the rear support substrate 21 have been described above with reference to the semiconductor component manufacturing method according to the first embodiment, and thus additional descriptions thereof will be omitted.

In a step of forming a third semiconductor component element 50 in the via hole 14, a process of forming the third semiconductor component element 50 inside the via hole 14 is performed. The process of forming the third semiconductor component element 50 may include a lithography process, an etching process, a deposition process, or the like.

For example, the third semiconductor component element 50 may be a conductive metal, and the process of forming the third semiconductor component element 50 may include forming a photoresist corresponding to the via hole 14 on one surface 13a of the device layer 13, plating a first conductive metal so that an interior of the via hole 14 is filled with the first conductive metal, and then removing the photoresist.

According to an embodiment, the step of forming the third semiconductor component element 50 in the via hole 14 may be performed between the step of forming the via hole 14 in the device layer 13 and the step of peeling the device layer 13 from the SOI wafer 10.

The steps of forming the first semiconductor component element 30 on one surface of the device layer 13, separating the device layer 13 from the rear support substrate 21, placing the device layer 13 on the front support substrate 22, forming the second semiconductor component element 40 on the opposite surface of the device layer 13, and separating the device layer 13 from the front support substrate 22 are similar to those described above with reference to the semiconductor component manufacturing method according to the first embodiment, and thus additional descriptions thereof will be omitted.

However, in the step of forming the first semiconductor component element 30 on one surface of the device layer 13, the first semiconductor component element 30 may be formed to be electrically connected to the third semiconductor component element 50. In addition, in the step of forming the second semiconductor component element 40 on the opposite surface of the device layer 13, the second semiconductor component element 40 may be formed to be electrically connected to the third semiconductor component element 50.

According to the semiconductor component manufacturing method of the present embodiment, the first semiconductor component element 30 and the second semiconductor component element 40 formed on both surfaces 13a and 13b of the device layer 13 may be electrically connected by the third semiconductor component element 50.

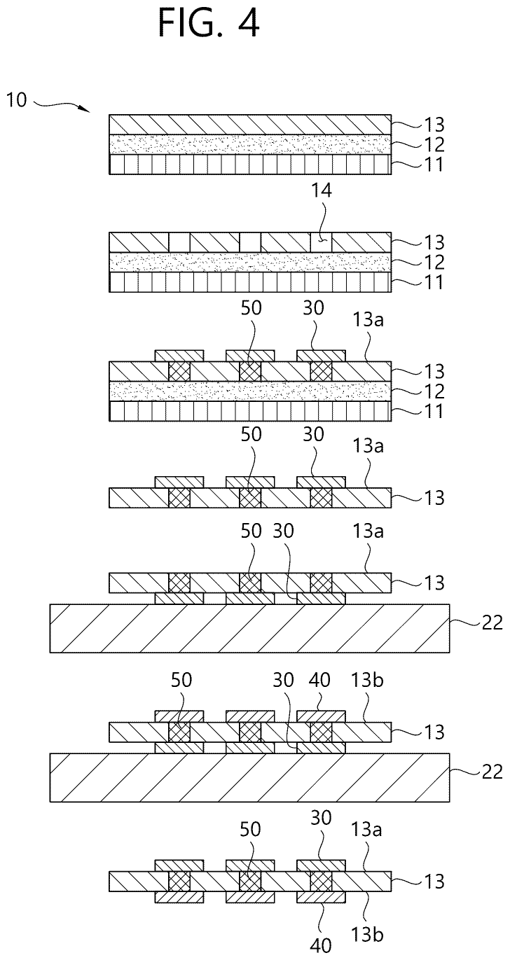

FIG. 4 is a diagram for explaining a semiconductor component manufacturing method according to a fourth embodiment of the present invention.

Referring to FIG. 4, a semiconductor component manufacturing method according to a fourth embodiment of the present invention differs from the semiconductor component manufacturing method according to the third embodiment described above in that a first semiconductor component element 30 and a third semiconductor component element 50 are formed on the SOI wafer 10, and thereafter the device layer 13 is peeled from the SOI wafer 10.

The semiconductor component manufacturing method according to the fourth embodiment of the present invention includes preparing an SOI wafer 10; forming a via hole 14 in a device layer 13; forming a third semiconductor component element 50 in the via hole 14; forming a first semiconductor component element 30 on one surface of the device layer 13 of the SOI wafer 10; peeling the device layer 13 from the SOI wafer 10; placing the device layer 13 on a front support substrate 22; forming a second semiconductor component element 40 on a opposite surface of the device layer 13; and separating the device layer 13 from the front support substrate 22.

Descriptions of the SOI wafer 10 have been provided above, and thus additional descriptions thereof will be omitted.

The step of forming the third semiconductor component element 50 in the via hole 14 is also similar to that described above with reference to the semiconductor component manufacturing method according to the third embodiment, and thus additional descriptions thereof will be omitted. However, in the present embodiment, the step of forming the third semiconductor component element 50 in the via hole 14 is performed prior to the step of peeling the device layer 13 from the SOI wafer 10, which is different from the semiconductor component manufacturing method according to the third embodiment.

The step of forming the first semiconductor component element 30 on one surface of the device layer 13 of the SOI wafer 10 is also similar to that described above with reference to the semiconductor component manufacturing method according to the third embodiment, and thus additional descriptions thereof will be omitted. However, in the present embodiment, the step of forming the first semiconductor component element 30 is performed prior to the step of peeling the device layer 13 from the SOI wafer 10, which is different from the semiconductor component manufacturing method according to the third embodiment.

The steps of peeling the device layer 13 from the SOI wafer 10, placing the device layer 13 on the front support substrate 22, forming the second semiconductor component element 40 on the opposite surface of the device layer 13, and separating the device layer 13 from the front support substrate 22 are similar to those described above with reference to the semiconductor component manufacturing method according to the second embodiment, and thus additional descriptions thereof will be omitted. Similar to the semiconductor component manufacturing method according to the second embodiment described above, the first semiconductor component element 30 and/or the second semiconductor component element 40 may be formed to be electrically connected to the third semiconductor component element 50.

Conventionally, in manufacturing semiconductor components using a wafer, a wafer thinning process is performed to thin the semiconductor components. Since a thin semiconductor substrate has high brittleness and thus may be fractured or damaged during transfer or semiconductor processing, a process of forming semiconductor devices on a front surface of a wafer having a thickness sufficient to secure rigidity is first performed, and thereafter a thinning process is carried out by physically or chemically etching a opposite surface of the wafer. Accordingly, semiconductor devices have been formed only on the front surface of the wafer and could not be formed on the opposite surface. In addition, since the thinning process is performed after the semiconductor devices are formed, the semiconductor devices may be physically and/or chemically damaged by the thinning process.

As described above, the semiconductor component manufacturing method according to the present invention includes peeling the device layer 13 from the SOI wafer 10, placing the peeled device layer 13 on support substrates 21 and 22, and fixing the device layer 13 while forming semiconductor component elements 30 and 40 on one surface or both surfaces of the device layer 13.

Accordingly, since a thinning process is not performed after forming the semiconductor component elements 30 and 40, damage to the semiconductor component elements 30 and 40 caused by the thinning process can be prevented.

In addition, the semiconductor component elements 30 and 40 can be formed on both surfaces 13a and 13b of the device layer 13, respectively.

In addition, since the peeled device layer 13 can be fixed to the support substrates 21 and 22 without using a separate adhesive, a high-temperature process can be performed while the device layer 13 is fixed to the support substrates 21 and 22.

Hereinafter, a thin-film actuator and a thin-film gripper according to embodiments of the present invention will be described. The thin-film actuator and the thin-film gripper according to embodiments of the present invention may be manufactured using the semiconductor component manufacturing methods according to the embodiments of the present invention described above.

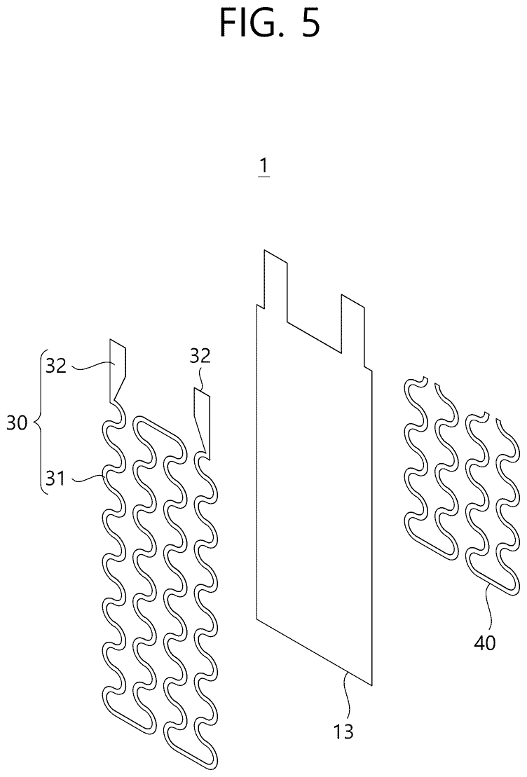

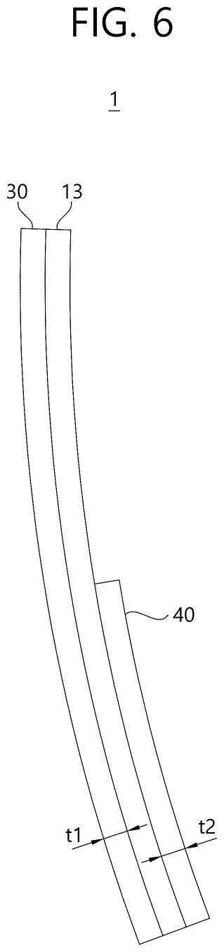

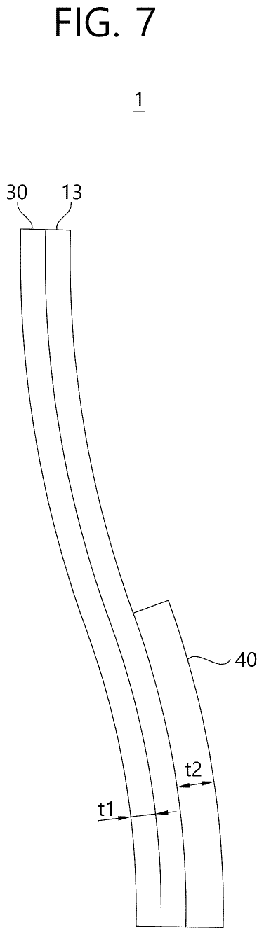

FIG. 5 is an exploded perspective view illustrating a thin-film actuator according to the first embodiment of the present invention, FIG. 6 is a schematic side view illustrating an operating state of the thin-film actuator according to the first embodiment of the present invention, and FIG. 7 is a schematic side view illustrating another embodiment of the thin-film actuator according to the first embodiment of the present invention.

Referring to FIGS. 5 through 7, a thin-film actuator 1 according to the first embodiment of the present invention includes a thin device layer 13, a heater layer 30 formed on one surface of the device layer 13, and a shape control layer 40 formed on the other surface of the device layer 13.

The device layer 13 may be the device layer 13 described in the semiconductor component manufacturing methods described above, the heater layer 30 may be the first semiconductor component element 30 described above, and the shape control layer 40 may be the second semiconductor component element 40 described above.

The heater layer 30 may include a heating layer 31 and a pair of electrodes 32 formed at opposite ends of the heating layer 31. When a current is applied through the electrodes 32, Joule heating is generated in the heating layer 31 due to the current, and the heating layer 31 expands.

The heating layer 31 is formed of a conductive material having a coefficient of thermal expansion different from that of the device layer 13.

Accordingly, when a current flows through the heater layer 30, due to the difference in coefficients of thermal expansion between the heating layer 31 and the device layer 13, the thin-film actuator 1 bends and deforms as illustrated in FIG. 6 or FIG. 7. When the current applied to the heater layer 30 is cut off and the heating layer 31 is cooled, the thin-film actuator 1 returns to its original state. The thin-film actuator 1 can function as an actuator by utilizing such deformation characteristics.

Meanwhile, the shape control layer 40 formed on the other surface of the device layer 13 controls a deformation shape of the thin-film actuator 1.

Referring to FIGS. 5 and 6, the shape control layer 40 has a thickness t2 equal to a thickness t1 of the heating layer 31, and is formed in the same pattern as the heating layer 31 from an end portion to a halfway point of the heating layer 31. In this case, compared to a case in which the shape control layer 40 is not formed, a degree of deformation at the end portion of the thin-film actuator 1 can be reduced.

Referring to FIGS. 5 and 7, the heater layer 30 has a thickness t2 greater than the thickness t1 of the heating layer 31 and is formed in the same pattern as the heating layer 31 from an end portion to a midpoint of the heating layer 31. In this case, compared to the case of FIG. 6, the end portion of the thin-film actuator 1 may be deformed into an approximately S-shaped form.

That is, the shape control layer 40 formed on a side opposite to the heater layer 30 with respect to the device layer 13 may adjust the deformation shape of the thin-film actuator 1 according to a degree of overlap with the heating layer 31, a shape, a thickness, and the like.

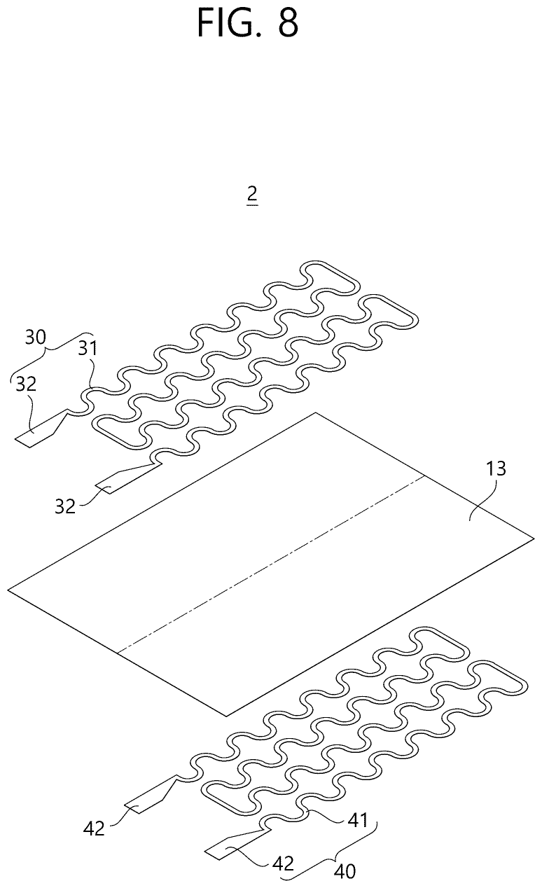

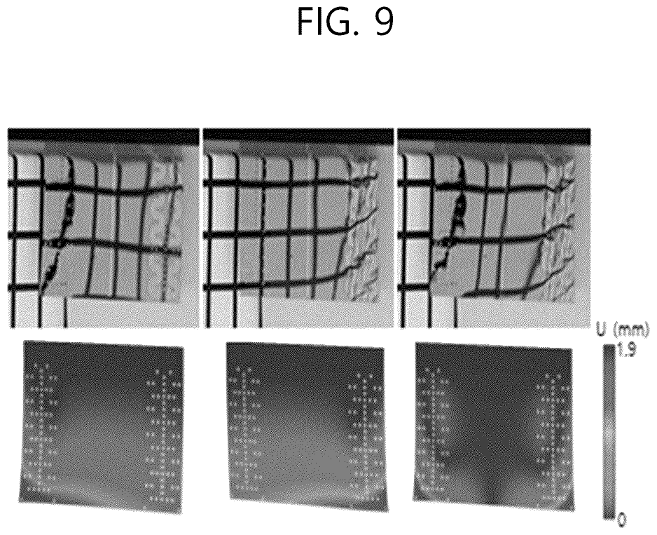

FIG. 8 is an exploded perspective view illustrating a thin-film actuator according to a second embodiment of the present invention, and FIG. 9 is an image illustrating an operating state of the thin-film actuator according to the second embodiment of the present invention.

Referring to FIG. 8, a thin-film actuator 2 according to the second embodiment of the present invention includes a thin device layer 13, a first heater layer 30 formed on one surface of the device layer 13, and a second heater layer 40 formed on the other surface of the device layer 13.

The device layer 13 is the device layer 13 described in the above semiconductor component manufacturing method, the first heater layer 30 may be the first semiconductor component element 30 described in the above semiconductor component manufacturing method, and the second heater layer 40 may be the second semiconductor component element 40 described in the above semiconductor component manufacturing method.

The first heater layer 30 may include a first heating layer 31 and a pair of first electrodes 32 formed at both ends of the first heating layer 31. When a current is applied through the first electrodes 32, Joule heating is generated in the first heating layer 31 by the current, and the first heating layer 31 expands. The first heating layer 31 is formed of a conductive material having a coefficient of thermal expansion different from that of the device layer 13.

The second heater layer 40 may include a second heating layer 41 and a pair of second electrodes 42 formed at both ends of the second heating layer 41. When a current is applied through the second electrodes 42, Joule heating is generated in the second heating layer 41 by the current, and the second heating layer 41 expands. The second heating layer 41 is formed of a conductive material having a coefficient of thermal expansion different from that of the device layer 13.

The first heater layer 30 and the second heater layer 40 may bend the device layer 13 in different directions.

Referring to FIG. 8, the first heater layer 30 may be formed on one side of one surface of the device layer 13 (to the left of the one-dot chain line in FIG. 8), and the second heater layer 40 may be formed on the other side of the other surface of the device layer 13 (to the right of the one-dot chain line in FIG. 8). That is, the first heater layer 30 and the second heater layer 40 may be formed such that at least portions thereof do not overlap each other with the device layer 13 interposed therebetween.

In this case, when a current is applied to the first heater layer 30 and no current is applied to the second heater layer 40, the thin-film actuator 2 may be bent as shown in the left image of FIG. 9. When no current is applied to the first heater layer 30 and a current is applied to the second heater layer 40, the thin-film actuator 2 may be bent as shown in the center image of FIG. 9. When currents are applied to both the first heater layer 30 and the second heater layer 40, the thin-film actuator 2 may be bent as shown in the right image of FIG. 9.

The thin-film actuator 2 may function as an actuator by utilizing such deformation characteristics.

Although FIGS. 8 and 9 illustrate an example in which the first heater layer 30 and the second heater layer 40 are formed such that at least portions thereof do not overlap each other with the device layer 13 interposed therebetween, the first heater layer 30 and the second heater layer 40 may be formed to overlap each other. In this case, by independently applying currents to the first heater layer 30 and the second heater layer 40, a thin-film actuator having deformation characteristics different from those illustrated in FIG. 9 may be manufactured.

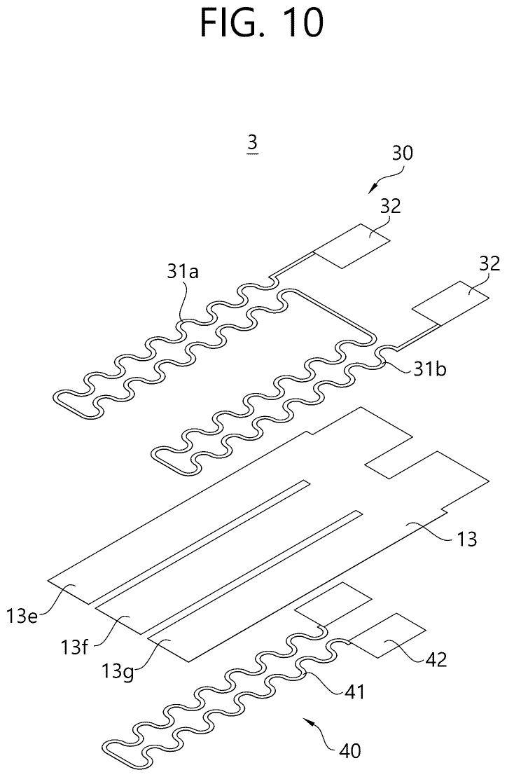

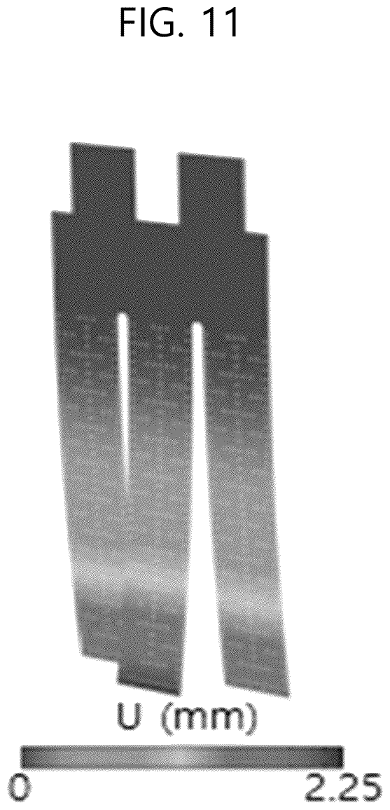

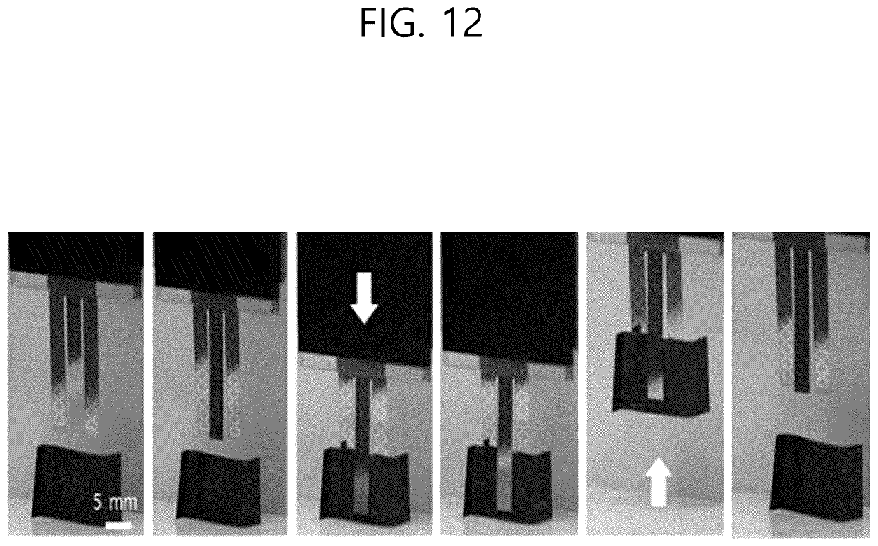

FIG. 10 is an exploded perspective view illustrating a thin-film gripper according to an embodiment of the present invention, FIG. 11 is an image illustrating operation simulation results of the thin-film gripper according to an embodiment of the present invention, and FIG. 12 is an image illustrating a pick-and-place operation using the thin-film gripper according to an embodiment of the present invention.

Referring to FIG. 10, a thin-film gripper 3 according to a second embodiment of the present invention includes a thin device layer 13, a first heater layer 30 formed on one surface of the device layer 13, and a second heater layer 40 formed on the other surface of the device layer 13.

The device layer 13 is the device layer 13 described in the above semiconductor component manufacturing method, the first heater layer 30 may be the first semiconductor component element 30 described in the above semiconductor component manufacturing method, and the second heater layer 40 may be the second semiconductor component element 40 described in the above semiconductor component manufacturing method.

The device layer 13 may include a first finger thin film 13e, a second finger thin film 13f, and a third finger thin film 13g formed adjacent to each other.

The first heater layer 30 may include a first heating layer 31a, a third heating layer 31b electrically connected to the first heating layer 31a, and a pair of first electrodes 32 respectively formed at one end of the first heating layer 31a and one end of the third heating layer 31b. The first heating layer 31a may be formed on one surface of the first finger thin film 13e, and the third heating layer 31b may be formed on one surface of the third finger thin film 13g.

When a current is applied through the first electrodes 32, Joule heating is generated in the first heating layer 31a and the third heating layer 31b by the current, and the first heating layer 31a and the third heating layer 31b expand. The first heating layer 31a and the third heating layer 31b are formed of conductive materials having coefficients of thermal expansion different from that of the device layer 13.

Accordingly, as the first heating layer 31a and the third heating layer 31b are heated, the first finger thin film 13e and the third finger thin film 13g may be bent in one direction (upward with respect to FIG. 10). When the current applied to the first heating layer 31a and the third heating layer 31b is cut off and the first heating layer 31a and the third heating layer 31b are cooled, the first finger thin film 13e and the third finger thin film 13g return to their original states.

The second heater layer 40 may include a second heating layer 41 and a pair of second electrodes 42 formed at both ends of the second heating layer 41. When a current is applied through the second electrodes 42, Joule heating is generated in the second heating layer 41 by the current, and the second heating layer 41 expands. The second heating layer 41 is formed of a conductive material having a coefficient of thermal expansion different from that of the device layer 13.

Accordingly, as the second heating layer 41 is heated, the second finger thin film 13f may be bent in the other direction (downward with respect to FIG. 10). When the current applied to the second heating layer 41 is cut off and the second heating layer 41 is cooled, the second finger thin film 13f returns to its original state.

Referring to FIG. 11, as currents are respectively applied to the first heating layer 31a, the second heating layer 41, and the third heating layer 31b, the first finger thin film 13e and the third finger thin film 13g are bent in one direction, and the second finger thin film 13f is bent in the other direction, thereby forming a spaced region between the second finger thin film 13f and the first finger thin film 13e/the third finger thin film 13g. Accordingly, the thin-film gripper may function as a gripper configured to grasp an object entering the spaced region.

Referring to FIG. 12, the bottom image illustrates a state in which no current is applied to the first heating layer 31a, the second heating layer 41, and the third heating layer 31b. The second image from the bottom illustrates a state in which currents are respectively applied to the first heating layer 31a, the second heating layer 41, and the third heating layer 31b such that the first finger thin film 13e, the second finger thin film 13f, and the third finger thin film 13g are bent. The third image from the bottom illustrates a state in which, while the first finger thin film 13e, the second finger thin film 13f, and the third finger thin film 13g are bent, the gripper descends toward an object such that a portion of the object is positioned between the second finger thin film 13f and the first finger thin film 13e/the third finger thin film 13g. The fourth image from the bottom illustrates a state in which the current applied to the first heating layer 31a, the second heating layer 41, and the third heating layer 31b is cut off such that the first finger thin film 13e, the second finger thin film 13f, and the third finger thin film 13g grasp the object. The fifth image from the bottom illustrates a state in which the thin-film gripper 3 is lifted while the first finger thin film 13e, the second finger thin film 13f, and the third finger thin film 13g grasp the object. The top image illustrates a state in which currents are respectively applied to the first heating layer 31a, the second heating layer 41, and the third heating layer 31b to bend the first finger thin film 13e, the second finger thin film 13f, and the third finger thin film 13g, thereby releasing the object.

As illustrated in FIG. 12, the thin-film gripper 3 according to an embodiment of the present invention may perform a pick-and-place operation on an object having a micro-scale structure.

Although FIGS. 10 to 12 illustrate an example in which three finger thin films 13e, 13f, and 13g are formed, according to embodiments, the thin-film gripper 3 may include two finger thin films 13e and 13f or four or more finger thin films.

Although embodiments of the present disclosure have been described with reference to the accompanying drawings, a person with ordinary knowledge in the technical field to which the present disclosure belongs will be able to understand that the present disclosure may be implemented in other specific forms without changing the technical spirit or essential features. Therefore, the embodiments described above should be understood as illustrative in all respects and not limiting. The scope of the present disclosure is indicated by claims to be described later rather than the detailed description above, and all changes or modified forms derived from the meaning and scope of the claims and their equivalent concepts should be construed as being included in the scope of the present disclosure.

What is claimed is:

1. A method for manufacturing a semiconductor component, comprising:
preparing a thin device layer having a first semiconductor component element formed on one surface thereof;
placing the device layer on a front-side support substrate such that the one surface of the device layer is in direct contact with the front-side support substrate;
forming a second semiconductor component element on an opposite surface of the device layer facing away from the one surface; and
separating the device layer from the front-side support substrate,
wherein, in placing the device layer on the front-side support substrate, the device layer is fixed to the front-side support substrate by a van der Waals force acting between the device layer and the front-side support substrate.

2. The method of claim 1,
wherein the device layer is separated from a wafer including a handling layer, a silicon oxide layer stacked on the handling layer, and the device layer stacked on the silicon oxide layer.

3. The method of claim 1,
wherein placing the device layer on the front-side support substrate comprises:
placing the device layer on the front-side support substrate in a predetermined solution; and
drying the predetermined solution while the device layer is placed on the front-side support substrate so that the device layer is fixed to the front-side support substrate by the van der Waals force.

4. The method of claim 1,
wherein separating the device layer from the front-side support substrate comprises applying a separation solution to the device layer and the front-side support substrate such that the device layer is peeled off from the front-side support substrate.

5. The method of claim 1, further comprising:
preparing a wafer including a handling layer, a silicon oxide layer stacked on the handling layer, and the device layer stacked on the silicon oxide layer;
removing the silicon oxide layer to separate the device layer;
placing the device layer on a back-side support substrate such that the opposite surface of the device layer faces the back-side support substrate;
forming the first semiconductor component element on the one surface of the device layer; and
separating the device layer from the back-side support substrate.

6. The method of claim 5,
wherein removing the silicon oxide layer to separate the device layer comprises:
applying an etching solution that selectively etches silicon oxide to the wafer to remove the silicon oxide layer; and
applying a separation solution to the wafer from which the silicon oxide layer has been removed to peel the device layer from the handling layer.

7. The method of claim 6,
wherein placing the device layer on the back-side support substrate comprises:
inserting the back-side support substrate between the device layer and the handling layer; and
drying the separation solution while the device layer is placed on the back-side support substrate so that the device layer is fixed to the back-side support substrate by the van der Waals force.

8. The method of claim 1, further comprising:
forming at least one via hole in the device layer to connect the one surface and the opposite surface of the device layer;
forming a third semiconductor component element in the via hole; and
forming the first semiconductor component element on the one surface so as to be electrically connected to the third semiconductor component element.

9. The method of claim 8,
wherein forming the second semiconductor component element comprises forming the second semiconductor component element on the opposite surface so as to be electrically connected to the third semiconductor component element.

10. The method of claim 1,
wherein no adhesive material is present between the device layer and the front-side support substrate.
